(19) United States
(12) Patent Application Publication
(10) Pub. No.: US 2002/0127336 A1
(43) Pub. Date: Sep. 12, 2002

(54) Method for growing thin films by catalytic enhancement

(75) Inventors: Ling Chen, Sunnyvale, CA (US); Wei Cao, Milpitas, CA (US)

Correspondence Address: PATENT COUNSEL, APPLIED MATERIALS, INC., Legal Affairs Department, P.O. BOX 450A, Santa Clara, CA, 95052, US

(73) Assignee: APPLIED MATERIALS, INC.

(21) Appl. No.: 10/050,654

(22) Filed: Jan. 16, 2002

Related U.S. Application Data
(60) Provisional application No. 60/261,946, filed on Jan. 16, 2001.

(51) Int. Cl. C23C 16/00

(52) U.S. Cl. 427/250; 427/248.1

(57) ABSTRACT

A method of growing a thin film onto a substrate. A precursor of the film is fed into a reaction space in the form of a vapor phase pulse causing the precursor to adsorb onto the surface of the substrate to form a layer thereof. A catalyst is susequently fed into the reaction space in an amount to substantially convert the layer of the precursor to the desired thin film. The above steps may be repeated to achieve the desired film thickness.

### RELATED APPLICATIONS

This application claims benefit of provisional application No. 60/261,946, filed Jan, 16, 2001.

### TECHNICAL FIELD

The present invention relates to a method of growing thin films on substrates in a reaction space being subjected to alternately repeated steps of feeding a precursor followed by feeding a catalyst for the precursor to grow the desired thin film.

### BACKGROUND OF THE INVENTION

There are a variety of methods employed in the art of growing thin films. For example, chemical vapor deposition (CVD) has been used for many years to deposit solid thin films for a variety of commercial products including integrated circuits. The CVD method consists of exposing a substrate in a reaction chamber to one or more gaseous species that react to form a solid thin film on the substrate surface. CVD may be carried out at atmospheric or sub-atmospheric pressures, and usually requires that the reactivity of the gases be enhanced by heating the substrate or by creating a glow discharge in the reaction chamber. One of the disadvantages of the CVD method is that the gases may take part in undesired gas phase reactions. These undesired gas phase reactions may lead to the formation of particulates, and may also deplete the seed gases before they can reach all areas of the substrate. Thus, the undesired gas phase reactions can impact the quality and uniformity of the thin film being deposited.

An example of a specific CVD process is disclosed in U.S. Pat. No. 6,110,530 assigned to the assignee of the present application. The '530 patent discloses a CVD process for depositing a solid thin film of copper that employs a single gaseous precursor to form the copper layer. Although that precursor, hexafluoracetylacetonate-Cu-trimethylvinylsilane (hereinafter hfac-Cu-TMVS), is sufficiently reactive to deposit copper at temperatures below 200° C., the copper deposition rate is undesirably slow. It is, however, undesirable to raise the processing temperature to increase the reaction rate because, among other reasons, higher processing temperatures may degrade previously deposited layers on the substrate. It was found that the slow deposition rate at lower temperatures could be increased by adding water to the hfac -Cu-TMVS precursor. It appears that the water may act as a catalyst, facilitating the decomposition of hfac-Cu-TMVS at lower temperatures. Although the addition of water avoids the need to carry out the CVD deposition at higher temperatures, the problem of undesired gas phase reactions remains. Specifically, the addition of water also facilitates the decomposition of hfac-Cu-TMVS in the gas phase, which can lead to problems such as particulate formation. In other words, catalytically converting the copper precursor to elemental copper with water during a single processing step within the reaction chamber, although having certain advantages, suffers from processing limitations to which the present invention is intended to address.

When a CVD reaction requires more than one gaseous reactant, undesired gas phase reactions between them can by avoided by separately and sequentially introducing the gaseous reactants into the reaction chamber. One method that employs the separate and sequential introduction of gaseous reactants is the Atomic Layer Deposition (ALD) method, one version of which is described in U.S. Pat. No. 4,058,430. In ALD, the substrate is heated to a temperature such that when a first gas is introduced into a reaction chamber, it chemisorbs on the substrate surface, forming a monolayer. An exact monolayer can be formed because the first layer of the gaseous species is relatively strongly bonded to the surface of the substrate by the chemisorption reaction while any excess reactant is relatively weakly bonded to the chemisorbed monolayer. The excess first gaseous reactant can then be removed from the reaction chamber. This removal may take place by, for example, evacuating the reaction chamber with a vacuum pump or by purging the reaction chamber with an inert gas. Ideally, the monolayer of the first gaseous species remains on the heated substrate surface after the removal of the excess reactant. Next, a second gaseous reactant is introduced into the reaction chamber. The second gaseous reactant reacts with the monolayer to produce the desired solid thin film. The excess of the second reactant, along with any reaction by-products, are then removed from the reaction chamber. Again, the removal may take place by means of evacuating the reaction chamber or purging the reaction chamber with an inert gas. A distinguishing characteristic of the ALD process is that it deposits a precise layer thickness each time the above sequence of steps is repeated. A precise layer thickness is obtained because of the formation of an exact monolayer of the first precursor. The above sequence of steps can be repeated until a thin film of desired thickness is created.

Although ALD may eliminate undesired gas phase reactions between multiple CVD precursors, ALD has a number of disadvantages that limit its utility. One of those disadvantages is that the ALD process can only be used with gaseous species that react with the substrate and with each other within a “temperature window”. The temperature window is defined by the constraints that the substrate temperature must be high enough for the second gaseous reactant to react with the chemisorbed monolayer of the first gaseous reactant, but the substrate temperature cannot be so high that the monolayer of the first reactant desorbs. This temperature window severely limits the number of species that are compatible with the ALD process. Furthermore, the temperature window limitation of ALD means that ALD cannot be used to deposit a film from a single gaseous species. The use of a single species is incompatible with ALD because the substrate temperature would have to be high enough for the species to react to form a solid film. Since the film formation reaction would consume any of the species introduced into the reactor, the precise thickness control characteristic of ALD would not be possible. In other words, the deposition process would degrade into CVD with a single reactant. Thus the precise layer control obtainable in ALD, which is made possible by separating the introduction of the gaseous reactants, cannot be achieved in a single species system.

### SUMMARY OF THE INVENTION

The present invention is directed to a method of growing a thin film onto a substrate. The method comprises feeding a single gaseous precursor into a reaction space. The precursor is caused to adsorb onto the surface of the substrate to form a layer. A catalyst is then fed into the reaction space in an amount to substantially convert the layer of the precursor into the desired thin film. Embodiments of the present invention overcome the shortcomings of previously available CVD and ALD methods.

### DETAILED DESCRIPTION OF THE INVENTION

It is now proposed to employ a catalyst in a process that employs a single gaseous precursor in such a manner that the precise layer thickness control of the ALD process can be obtained. Specifically, the process comprises the steps of introducing a single gaseous precursor into a reaction chamber under conditions such that a portion of the precursor adsorbs on the substrate and subsequently converting the adsorbed precursor to the desired thin film through the use of a suitable catalyst.

As illustrative of the present invention, reference is made once again to the creation of a thin film of copper metal on a substrate through the use of the precursor hfac-Cu-TMVS.

The copper film is produced pursuant to the following reaction:

2(hfac)-Cu-(TMVS)→Cu°+Cu (hfac)₂+2TMVS

It is known that water will catalytically promote this reaction. As such, the present invention contemplates introducing the precursor hfac-Cu-TMVS, into a reaction chamber, generally maintained at low pressure, causing the precursor to adsorb onto the substrate, which may be heated and which is located within the reaction chamber. Like in an ALD process, the adsorption may take place by means of chemisorbing an exact monolayer of the precursor onto the substrate. Formation of a monolayer in this manner will produce the type of precise layer control characteristic of an ALD process. On the other hand, it is also possible to carry out the claimed method under conditions in which the precursor physisorbs onto the substrate. When the precursor physisorbs onto the substrate, layer thickness control may be achieved, for example, by controlling the amount of precursor introduced into the reaction chamber. It is to be appreciated that the substrate temperature may be modified to facilitate the appropriate type of adsorption, which may differ for different applications of the claimed process.

After the precursor adsorbs onto the substrate in the appropriate manner, a catalyst is introduced into the chamber. The catalyst is chosen so that the adsorbed precursor reacts to form the desired thin film at the substrate temperature. The use of a catalyst allows the film formation reaction to occur at lower temperatures, so that the problem of high temperature desorption of the precursor can be ameliorated. Where the precursor is hfac-Cu-TMVS, a suitable catalyst is water. The introduction of water lowers the temperature required for hfac-Cu-TMVS to decompose into elemental copper. Specifically, the addition of water allows the substrate temperature to be less than about 150° C., and possibly as low as 100° C. The addition of a catalyst with a single precursor allows the deposition process to be carried out at temperatures low enough to prevent desorption of the precursor, yet high enough, due to the addition of the catalyst, to permit the film-formation reaction. Thus it is possible to extend some of the advantages of ALD to a single precursor system, while overcoming the disadvantages of prior art techniques.

The precursor and the catalyst may be introduced into the reaction chamber by any appropriate method. For example, the precursor could be introduced in the form of a gaseous stream of pure precursor, or the precursor entrained within a flow of a carrier gas. Similarly, the catalyst could be introduced alone or mixed with a carrier gas. The choice of carrier gas would be dictated by the precursor and catalyst chemistries. For the example system of hfac-Cu-TMVS and water, examples of suitable carrier gases are H₂, Ar and N₂.

After the precursor is adsorbed onto the substrate surface, but before the introduction of the catalyst into the reactor, any excess, or non-adsorbed, precursor may be removed from the proximity of the substrate. This removal of the precursor may be desirable in order to control the amount of precursor adsorbing on the substrate, or to prevent the precursor from reacting in the gas phase when catalyst is introduced into the reactor. In an alternative embodiment of the claimed method, however, precursor may continue to be introduced into the reaction chamber while the catalyst is introduced. This embodiment may be useful when the stoichiometry of the deposition reaction requires more than one precursor molecule. For example, in the deposition of copper from hfac-Cu-TMVS, two molecules of the precursor are needed to apply a single molecule of copper. As such, introducing additional precursor with the water catalyst encourages production of the final film.

When it is desired to remove excess or non-adsorbed precursor from the proximity of the substrate before introduction of the catalyst, any suitable method may be used to accomplish the removal. For example, the precursor could be removed by evacuating the reaction chamber with a vacuum pump. Alternatively, removal could occur by purging the reaction chamber with a gas. The purge could consist of flowing the gas between the introduction into the reaction chamber of flows of pure precursor and catalyst, or the purge could consist of flowing just the carrier gas while ceasing to introduce precursor or catalyst into the flow of carrier gas. The gas could be an inert gas such as Ar and N₂, or a gas that is not necessarily inert such as H₂. It is to be appreciated that when the precursor is removed by purging the reaction chamber, the extent of the purge may be varied. In other words, in some embodiments it may be desirable to purge the reaction chamber with a sufficient volume of purge gas so that the excess precursor is essentially completely removed from the reaction chamber. The volume of purge gas could be adjusted by varying the purge gas volumetric flow rate, the amount of time the purge gas flows through the reactor, or by varying the reactor pressure. In alternative embodiments, a smaller volume of purge gas could be used to remove the precursor from each localized area of the substrate before the catalyst arrives at that localized area. Using a smaller volume of purge gas in this manner could reduce the cycle time required for the process.

After the desired film-formation reactions have occurred, it may be desirable to remove the catalyst and any reaction products are removed from the proximity of the substrate. The same removal techniques described above are also suitable for removing the catalyst and reaction products from the reaction chamber. The above sequence of steps, the introduction of the precursor, the optional removal of excess precursor, introduction of catalyst, and the optional removal of catalyst and reaction products, may be thought of as the steps in a cycle. The cycle may be repeated to achieve the desired film thickness.

It is also possible to carry out the claimed method in such a manner that the conditions under which a particular step in the cycle is carried out may vary between different cycles. For example, the identity of precursor introduced into the reaction chamber could be changed between cycles. By changing the identity of the precursor, a laminated structure consisting of layers of different materials could be grown. In addition, the thickness of the various layers in the laminate structure could be varied by varying the amount of precursor introduced into the reaction chamber between different cycles. The amount of precursor introduced into the reaction chamber can be varied by changing the volumetric flow rate of the precursor, or by changing the amount of time the precursor flows into the reactor.

An apparatus useful in carrying out the proposed method could be the same apparatus generally employed in the formation of thin films by CVD or by ALD. For example, the exemplary process for copper deposition can be carried out on an xZ-series CVD reactor, which is marketed by Applied Materials, Inc. of Santa Clara, Calif. As such, on a standard CVD apparatus such as an xZ-series reactor, one possible embodiment of the claimed method would be to introduce the precursor hfac-Cu-TMVS into the reactor for a period of 3 seconds, introduce a purge gas into the reactor for 5 seconds, introduce water vapor into the reactor for 3 seconds, and finally introduce a purge gas into the reactor for 5 seconds. In this embodiment, the various gases are largely removed from the reactor chamber volume before the subsequent gas is introduced into the reactor chamber volume.

Although the claimed method may be carried out on a standard CVD reactor, it may be desirable to carry out the method on an apparatus with a gas delivery system designed to rapidly switch between different gas streams, and with a reactor chamber designed to minimize the residence time of gases flowing through the chamber. Use of such an apparatus could reduce the time required to carry out the claimed process, and could better control the flow of the various gases (precursor, catalyst, and carrier gas). Better control over gas flow would allow the time a particular gas is introduced into the chamber to be very short. For example, with the proper gas delivery system it is possible to switch between gases rapidly enough so each gas flows into the reactor for only a fraction of a second. For example, using an apparatus with a rapidly switching gas delivery system, one possible embodiment of the claimed method would be to introduce the precursor hfac-Cu-TMVS into the reactor for a period of 0.5 seconds, introduce a purge gas into the reactor for 0.5 seconds, introduce water vapor into the reactor for 0.5 seconds, and then introduce a purge gas into the reactor for 0.5 seconds. In this embodiment, the various gases are not necessarily completely removed from the reactor chamber volume before the subsequent gas is introduced into the reactor chamber volume.

An example of an apparatus with an improved gas delivery assembly and minimized reactor chamber volume comprises a reactor chamber that has a covering member with an expanding channel at a central portion of the covering member and having a bottom surface extending from the expanding channel to a peripheral portion of the covering member. One or more gas conduits are coupled to the expanding channel in which the one or more gas conduits are positioned at an angle from a center of the expanding channel. Another feature of the gas delivery assembly could comprise a first valve and a second valve. The first valve includes a first delivery line and a first purge line. The first delivery line comprises a first reactant gas inlet, a first reactant gas outlet, and a first valve seat assembly. The first purge line comprises a first purge gas inlet and a first purge gas outlet. The first purge gas outlet of the first purge line is in communication with the first delivery line downstream of the first valve seat assembly. The second valve includes a second delivery line and a second purge line. The second delivery line comprises a second reactant gas inlet, a second reactant gas outlet, and a second valve seat assembly. The second purge line comprises a second purge gas inlet and a second purge gas outlet. The second purge gas outlet of the second purge line is in communication with the second delivery line downstream of the second valve seat assembly. The reactor chamber could also comprise a substrate support having a substrate receiving surface. The chamber further includes a chamber lid having a passageway at a central portion of the chamber lid and a tapered bottom surface extending from the passageway to a peripheral portion of the chamber lid. The bottom surface of the chamber lid is shaped and sized to substantially cover the substrate receiving surface. One or more valves are coupled to the passageway, and one or more gas sources are coupled to each valve. In one aspect, the bottom surface of the chamber lid may be tapered. In another aspect, a reaction zone defined between the chamber lid and the substrate receiving surface may comprise a small volume. In still another aspect, the passageway may comprise a tapered expanding channel extending from the central portion of the chamber lid. The chamber could also comprise a substrate support having a substrate receiving surface. The chamber further comprises a chamber lid having an expanding channel extending from a central portion of the chamber lid and having a tapered bottom surface extending from the expanding channel to a peripheral portion of the chamber lid. One or more gas conduits are disposed around an upper portion of the expanding channel in which the one or more gas conduits are disposed at an angle from a center of the expanding channel. A choke is disposed on the chamber lid adjacent a perimeter of the tapered bottom surface.

One possible method of utilizing the optimized apparatus for depositing a material layer over a substrate structure comprises delivering a first reactant gas and a first purge gas through a first gas conduit in which the first reactant gas is provided in pulses and the first purge gas is provided in a continuous flow. The method further comprises delivering a second reactant gas and a second purge through a second gas conduit in which the second reactant gas is provided in pulses and the second purge gas is provided in a continuous flow.

Another method of delivering gases to a substrate in the optimized apparatus comprises providing one or more gases into the substrate processing chamber, reducing a velocity of the gases through non-adiabatic expansion, providing the gases to a central portion of the substrate, and directing the gases radially across the substrate from the central portion of the substrate to a peripheral portion of the substrate. Another method of delivering gases to a substrate in the apparatus comprises providing one or more gases to a central portion of the substrate and directing the gases radially at a substantially uniform velocity across the substrate from the central portion of the substrate to a peripheral portion of the substrate. A more complete description of an apparatus with an improved gas delivery assembly and minimized reactor chamber volume may be found in pending application 10/032,284 filed on Dec. 21, 2001, the disclosure of which is incorporated herein by reference.

It should be noted that although the present invention has been described with respect to the precursor, hfac-Cu-TMVS, employed together with water as the catalyst, this example is intended to be merely illustrative of the present invention directed to method of cyclically introducing a precursor and a catalyst into a reaction chamber in order to create a suitable film.

Although the present invention has been illustrated using a specific embodiment, the invention is not meant to be so limited. It is intended that the present invention be defined solely by the appended claims.

What is claimed is:

1. A method of growing a thin film onto a substrate located within a reaction chamber comprising feeding a precursor of said film into said reaction chamber, causing said precursor to adsorb onto the surface of the substrate to form a layer thereof, and feeding a catalyst into said reaction chamber in an amount to substantially convert said layer of said precursor to said thin film.

2. The method of claim 1 wherein any non-adsorbed precursor is removed from the proximity of the substrate before feeding the catalyst into the reaction chamber.

3. The method of claim 1 wherein subsequent to feeding the catalyst into the reaction chamber the catalyst is removed from the proximity of the substrate.

4. The method of claim 1 wherein said steps of feeding the precursor, removing excess precursor, feeding a catalyst, and removing catalyst and unwanted reaction products, are repeated to achieve a desired film thickness on said substrate.

5. The method of claim 3 wherein a purge gas is fed into said reaction space after said precursor but before said catalyst is fed to said reaction space.

6. The method of claim 5 wherein said purge gas is also introduced into said reaction space after said catalyst but before said precursor of a subsequent deposition cycle is fed to said reaction space.

7. The method of claim 1 wherein a carrier gas is introduced into said reaction chamber continuously during the practice of said method, whereby the carrier gas functions as a purge gas for said reaction chamber.

8. The method of claim 1 wherein said precursor comprises hexafluoracetylacetonate-Cu-trimethylvinylsilane.

9. The method of claim 8 wherein said catalyst comprises water and said film comprises copper.

10. The method of claim 1 wherein said substrate is heated.

11. A method of forming a copper film on a substrate comprising feeding a precursor of hexafluoracetylacetonate-Cu-trimethylvinylsilane into a reaction chamber, causing said precursor to adsorb onto the surface of said substrate to form a layer thereof, and feeding water as a catalyst into said reaction chamber in an amount to substantially form said copper film pursuant to the following reaction:
2(hfac)-Cu-(TMVS)→Cu°+Cu (hfac)₂+2TMVS.

12. A method of growing a thin film onto a substrate located with a reaction chamber comprising feeding a precursor of said film into said reaction chamber, causing said precursor to adsorb onto the surface of the substrate to form a layer thereof, and feeding a catalyst and said precursor into said reaction chamber in amounts to substantially convert said layer of said precursor to said thin film.

13. The method of claim 12 wherein any non-adsorbed precursor is removed from the proximity of the substrate before feeding the catalyst and precursor into the reaction chamber.

14. The method of claim 12 wherein subsequent to the step of feeding precursor and catalyst into the reaction chamber the catalyst, residual precursor, if any, and unwanted reaction products, if any, are removed from the reaction chamber.

15. The method of claim 14 wherein said steps of feeding the precursor, removing excess precursor, if any, feeding the catalyst and the precursor, and removing the catalyst and excess precursor, if any, and unwanted reaction products, if any, are repeated to achieve a desired film thickness on said substrate.

16. The method of claim 12 wherein purge gas is fed into said reaction chamber after said precursor but before said catalyst and precursor are fed to said reaction chamber.

17. The method of claim 16 wherein said purge gas is also introduced into said reaction chamber after said catalyst and precursor are simultaneously introduced, but before said precursor of a subsequent deposition cycle is fed to said reaction chamber.

18. The method of claim 12 wherein purge gas is introduced into said reaction chamber continuously during the practice of said method, whereby the purge gas functions as a carrier gas.

19. The method of claim 12 wherein said precursor comprises hexafluoracetylacetonate-Cu-trimethylvinylsilane.

20. The method of claim 19 wherein said catalyst comprises water and said film comprises copper.
